(19) United States
(12) Patent Application Publication
(10) Pub. No.: US 2007/0187730 A1
(43) Pub. Date: Aug. 16, 2007

(54) Memory devices having charge trap layers

(75) Inventors: Sang-Jin Park, Yongin-si (KR); Young-kwan Cha, Suwon-si (KR); Young-soo Park, Suwon-si (KR); Jung-hyun Lee, Yongin-si (KR); Suk-ho Choi, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/635,047

(22) Filed: Dec. 7, 2006

(30) Foreign Application Priority Data
Feb. 11, 2006 (KR) 10-2006-0013331

(51) Int. Cl. H01L 29/76

(52) U.S. Cl. 257/288

(57) ABSTRACT

Example embodiments may provide memory devices having a charge trap layer which includes a hole trap and an electron trap. The memory device may generate a relatively large flat band voltage gap according to an applied bias voltage. Accordingly, a stable multilevel cell may be realized.

### PRIORITY STATEMENT

This application claims priority under 35 U.S.C. § 119 to Korean Patent Application No. 10-2006-0013331, filed on Feb. 11, 2006, in the Korean Intellectual Property Office (KIPO), the entire disclosure of which is incorporated herein by reference.

### BACKGROUND

Example embodiments relate to memory devices. For example, memory devices that write and read data using the trap characteristics of electric charges, and additionally, to memory devices having a first trapping layer where hole trapping occurs and a second trapping layer where electron trapping occurs.

### DESCRIPTION OF THE CONVENTIONAL ART

Various types of memory devices are produced in the conventional art. FIG. 1 is a cross-sectional view of a structure of a SONOS-type memory device 10 that uses a charge trap layer as a storage node. A source region S and a drain region D are formed on a substrate 11. Additionally, a tunnel insulating film 12, a charge trap layer 13, and a blocking insulating film 14 are stacked on the substrate 11. A gate electrode 15 is formed on the blocking insulating film 14. The tunnel insulating film 12 and the blocking insulating film 14 may be formed of SiO₂. The charge trap layer 13 may be a Si₃N₄ layer.

When a positively (+) biased voltage is applied to the gate electrode 15, electrons may be gathered in the charge trap layer 13. Accordingly, electrical characteristics at the charge trap layer 13 may be changed according to the variation of an electrical field that acts on a channel between the source S and drain D regions. According to the degree of electron trapping in the charge trap layer 13, a “1” or “0” value may be stored in the memory device 10, and therefore, the memory device 10 may read and/or write 1-bit data.

FIG. 2A is a graph showing a data programming characteristic of the memory device 10 of FIG. 1, and FIG. 2B is a graph showing a data erasing characteristic of the memory device 10 of FIG. 1. FIG. 2A shows a flat band voltage V_{FB} with respect to time (e.g., programming time) for applying a bias voltage to the memory device 10. The flat band voltage V_{FB} increases as the programming time increases because more electrons may be trapped in the charge trap layer 13 as the programming time increases. As shown in FIGS. 2A and 2B, in the example of memory device 10, the flat band voltage V_{FB} of the data programming characteristic and the data erasing characteristic is shifted toward a positive (+) voltage. That is, the flat band voltage V_{FB} may tend to shift toward a positive (+) voltage.

Data in the storage node 13 may be erased by removing electrons from the charge trap layer 13. For example, a negatively biased voltage (−) may be applied to the memory device 10 to remove electrons from the charge trap layer 13. Referring to FIG. 2B, when stored data is erased, the flat band voltage V_{FB} may be saturated at −3 V.

The charge trap layer 13 may be formed of a silicon rich oxide (SRO) such as SiO_{1.5} or silicon nano-crystal (Si-nc). In this example, the flat band voltage V_{FB} Of the data programming characteristic and the data erasing characteristic tend to be biased toward a negative (−) voltage. This may be due to holes being trapped in the charge trap layer 13 and the charge trap layer 13 including a lot of combining portions between Si atoms that may trap holes relatively easily. Additionally, because the flat band voltage V_{FB} is shifted toward a negative (−) voltage, the realization of a multilevel cell which may identify various levels is difficult.

### SUMMARY

Example embodiments may provide memory devices having a more evenly distributed flat band voltage without being biased toward a positive (+) or negative (−) voltage, and memory devices that can write two or more bits of data. For example, the memory devices may be non-volatile memory devices with multi-level bit capabilities.

According to example embodiments, memory devices may be provided which may include a tunnel insulating film on a substrate, a charge trap layer on the insulating film, including a hole trap and an electron trap, a blocking insulating film on the charge trap layer, and a gate electrode on the blocking insulating film.

In an example embodiment, the hole trap may be a first trap layer.

In an example embodiment, the electron trap may be a second trap layer.

In an example embodiment, the second trap layer may be formed on the first trap layer.

In an example embodiment, the second trap layer may be formed of silicon nitride.

In an example embodiment, the first trap layer may be formed of one of a silicon rich oxide and a silicon nano-crystal.

In an example embodiment, the blocking insulating film may be an insulating film having a higher dielectric constant than silicon oxide.

In an example embodiment, the electron trap may be an interface between the blocking insulating film and the charge trap layer.

In an example embodiment, the insulating film may be formed of a high k dielectric material.

In an example embodiment, the high k dielectric material may be selected from the group consisting of HfO₂, SiNₓ, Ta₂O₅, Al₂O₃, TiO₂, and PZT.

In an example embodiment, the memory device may further include a source region and a drain region in the substrate.

In an example embodiment, the charge trap layer may be a storage node that stores multi-bit data.

According to example embodiments, there may be provided a method of manufacturing a memory device which includes forming a tunnel insulating film on a substrate, forming a charge trap layer formed on the insulating film, forming a blocking insulating film on the charge trap layer, and forming a gate electrode on the blocking insulating film. In at least one example embodiment, the charge trap layer includes a hole trap and an electron trap.

In an example embodiment, the charge trap layer may be a storage node that stores multi-bit data.

In an example embodiment, the method may further include forming a source and drain region in the substrate.

In an example embodiment, the blocking insulating film may be an insulating film which has a higher dielectric constant than silicon oxide.

In an example embodiment, the electron trap is an interface between the blocking insulating film and the charge trap layer.

In an example embodiment, the insulating film may be formed of a high k dielectric material.

In an example embodiment, the high k dielectric material may be selected from the group consisting of HfO₂, SiNₓ, Ta₂O₅, Al₂O₃, TiO₂, and PZT.

In an example embodiment, the hole trap may be a first trap layer, and the electron trap may be a second trap layer.

In an example embodiment, the first trap layer may be formed of one of a silicon rich oxide and a silicon nano-crystal, and the second trap layer may be formed of silicon nitride.

### BRIEF DESCRIPTION OF THE DRAWINGS

Example embodiments will become more apparent by describing them in detail with reference to the attached drawings in which:

FIG. 1 is a cross-sectional view of a conventional non-volatile memory device;

FIGS. 2A and 2B are graphs showing a data programming characteristic and a data erasing characteristic, respectively, of the non-volatile memory device of FIG. 1;

FIG. 3 is a cross-sectional view of a memory device, according to an example embodiment;

FIG. 4 is a cross-sectional view of a memory device, according to another example embodiment;

FIG. 5 is a graph showing a voltage characteristic with respect to a capacitance of the memory device of FIG. 4;

FIG. 6 is a graph showing programming and erasing characteristics as a function of bias voltage application time; and

FIG. 7 is a graph showing the flat band voltage of the memory device of FIG. 4 as a function of time, according to an example embodiment.

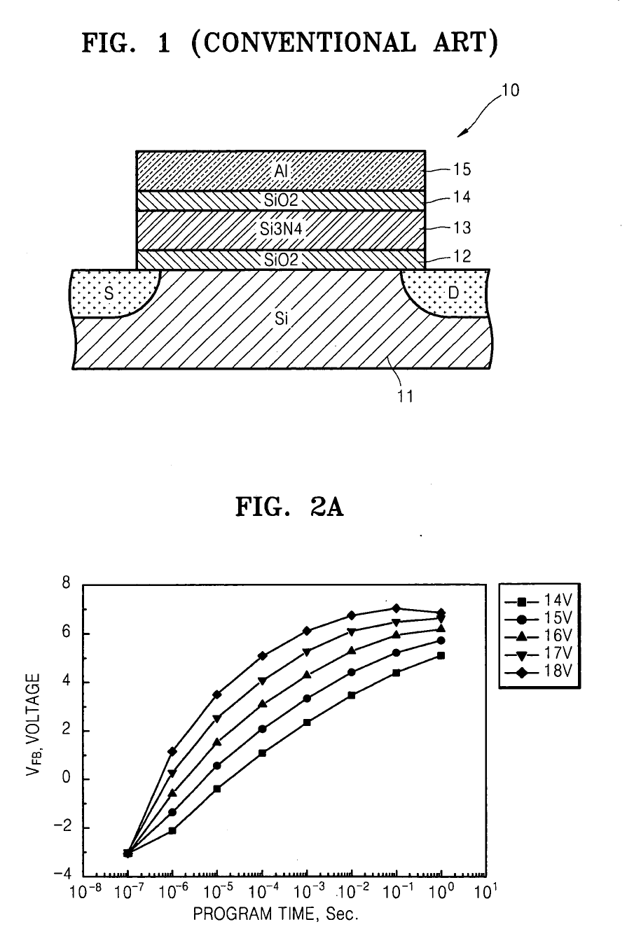

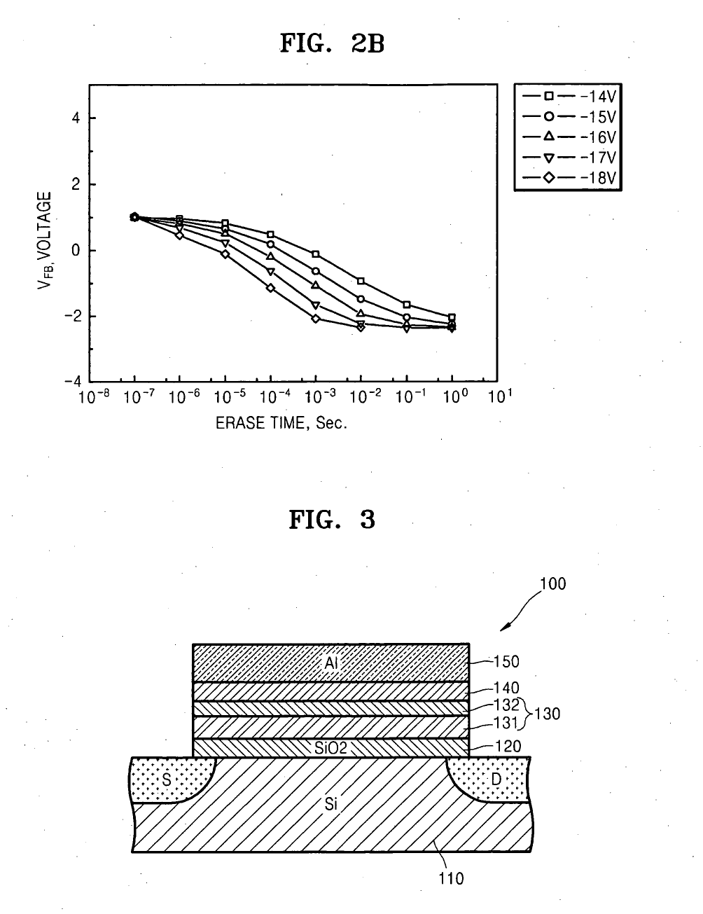

### DETAILED DESCRIPTION

Detailed example embodiments are disclosed herein. However, specific structural and functional details disclosed herein are merely representative for purposes of describing example embodiments. Example embodiments may, however, be embodied in many alternate forms and should not be construed as limited to only the example embodiments set forth herein.

Accordingly, while example embodiments are capable of various modifications and alternative forms, example embodiments are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular example embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

A non-volatile memory device having a charge trap layer, according to an example embodiment, will now be described more fully with reference to the accompanying drawings.

FIG. 3 is a cross-sectional view of a memory device (e.g., a non-volatile memory device), according to an example embodiment. The memory device 100 may have a structure in which a tunnel insulating film 120, a charge trap layer 130, a blocking insulating film 140, and a gate electrode 150 may be stacked on a substrate 110. A source region S and a drain region D may be formed in the substrate 110 on both sides of the tunnel insulating film 120.

The tunnel insulating film 120 may be formed of SiO₂ or any suitable insulator.

The charge trap layer 130 may include a hole trap layer 131 where hole trapping occurs and an electron trap layer 132 where electron trapping occurs. The electron trap layer 132 may be formed on the hole trap layer 131.

In at least one example embodiment, a large number of holes may be trapped in the hole trap layer 131. In another example embodiment, the majority of trapped holes may be trapped in the hole trap layer 131. In another example embodiment, an overwhelming number of holes may be trapped in the hole trap layer 131.

In at least one example embodiment, a large number of electrons may be trapped in the electron trap layer 132. In another example embodiment, the majority of trapped electrons are trapped in the electron trap layer 132. In another example embodiment, an overwhelming number of electrons are trapped in the electron trap layer 132.

The hole trap layer 131 may be formed of a silicon rich oxide (SRO) such as SiO_{1.5} or silicon nano crystal (Si-nc). The hole trap layer 131 may include combining portions between Si atoms that readily trap holes, thus hole trapping may occur in the hole trap layer 131. Accordingly, the hole trap layer 131 may induce the flat band voltage of the non-volatile memory device 100 to shift toward a negative (−) voltage.

The electron trap layer 132 may be formed of Si₃N₄. The electron trap layer 132 may induce the flat band voltage to shift toward a positive (+) voltage.

Accordingly, the memory device 100, according to example embodiments, may have the tendency of shifting the flat band voltage toward both negative and positive voltages, which may increase the width of the flat band voltage.

The blocking insulating film 140 may be formed of SiO₂ or any suitable insulator. The gate electrode 150 may be formed of aluminum (Al) or any suitable conductor.

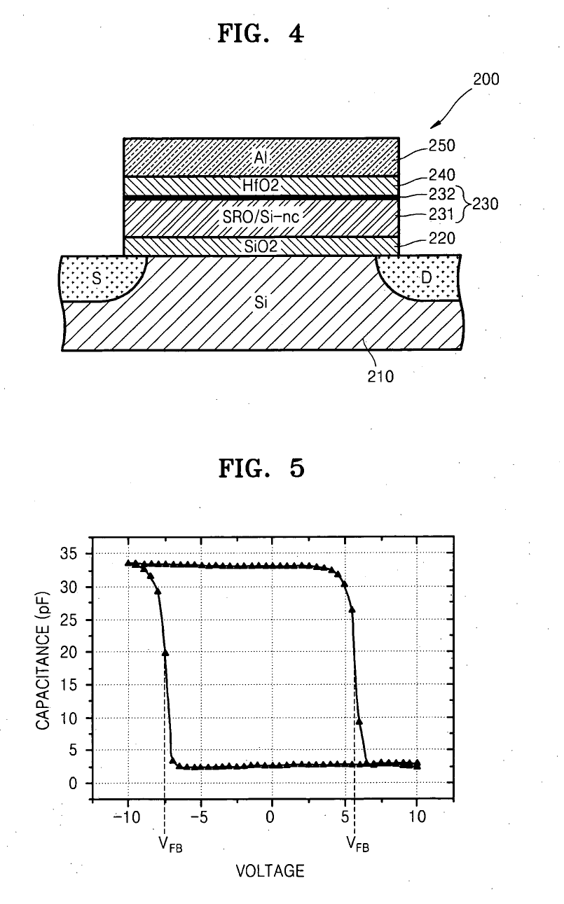

FIG. 4 is a cross-sectional view of a memory device (e.g., a non-volatile memory device), according to an example embodiment. The memory device 200 may have a tunnel insulating film 220, a charge trap layer 230, a blocking insulating film 240, and a gate electrode 250 stacked on a substrate 210 in which a source region S and drain region D may be formed.

The tunnel insulating film 220 may be formed of SiO₂ or any suitable insulator.

The charge trap layer 230 may include a hole trap layer 231 where hole trapping occurs and an electron trap 232 where electron trapping occurs. In at least one example embodiment, the electron trap 232 may be formed on the hole trap layer 231.

The hole trap layer 231 may be formed of a SRO such as SiO_{1.5} or silicon nano crystal (Si-nc). The hole trap layer 231 may include combining portions between Si atoms that readily trap holes, thus the hole trap layer 231 may trap holes. Accordingly, the hole trap layer 231 may have a tendency to shift a flat band voltage of the non-volatile memory device 200 toward a negative (−) voltage.

The electron trap 232 may be an interface between the blocking insulating film 240 and the hole trap layer 231. The blocking insulating film 240 may be formed of a dielectric material layer having a high dielectric constant (e.g., high “k” or κ dielectric layer), for example, a HfO₂ layer, having a dielectric constant which is relatively higher than that of silicon oxide. In example embodiments, other high k dielectric materials such as SiNₓ, Ta₂O₅, Al₂O₃, TiO₂, and PZT may be used to form the blocking insulating film 240. Electrons may be trapped in the electron trap 232 between the blocking insulating film 240 and the hole trap layer 231. Electron trapping at the interface between an HfO₂ layer and a silicon oxide layer (or a silicon nano crystal layer) has been disclosed. For example, when a blocking insulating film 240 formed of HfO₂ is stacked on the tunnel insulating film 220, an interface between the tunnel insulating film 220 and the blocking insulating film 240 may act as a charge trap or charge trap layer, and the flat band voltage tends to shift toward a positive (+) voltage. Accordingly, in some example embodiments, an additional electron trap layer may not be included, but the blocking insulating film 240 may be formed of a material having a relatively high dielectric constant such that electrons may be trapped at the interface between the tunnel insulating film 220 and the hole trap layer 231.

FIG. 5 is a graph showing a hysteresis curve of capacitance versus applied voltage of the memory device 200 of FIG. 4. From the graph, it can be seen that a flat band voltage V_{FB} of the memory device 200, having a range of approximately −7.5V to +5.5V may be uniformly distributed toward positive and negative voltages around 1V which is caused by the work function difference between Si and Al. Thus, the flat band voltage V_{FB} may be uniformly distributed over positive and negative voltages while the electron trap 232 and the hole trap layer 131 trap electrons and holes, respectively.

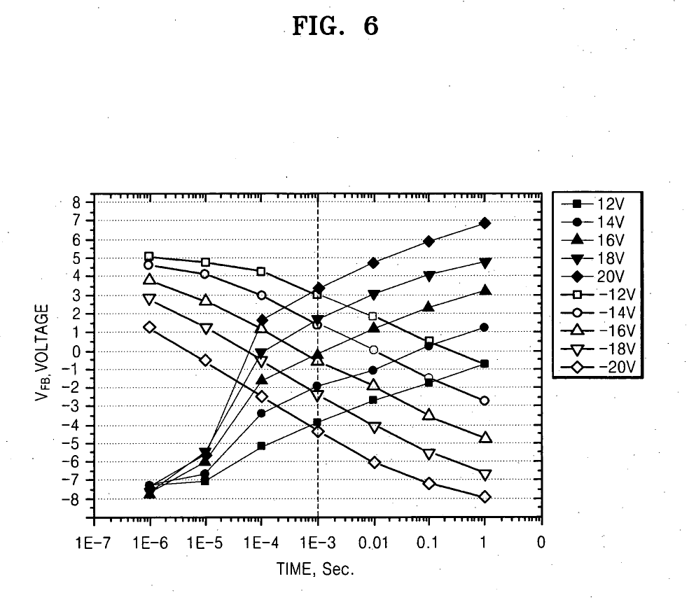

FIG. 6 is a graph showing programming and erasing characteristics as a function of bias voltage application time. Referring to FIG. 6, the flat band voltage may be widely distributed over positive and negative voltages, thus, it can be seen that a voltage gap between flat band voltages formed when different bias voltages are applied to the memory device 200 for the same length of time is relatively large. This may enable the realization of a multilevel cell. For example, as depicted in FIG. 6, when data is written for 100 us or erased for 10 ms by applying bias voltages with a 2V difference, the voltage gap between the flat band voltages is approximately 1.5V. That is, when a flat band voltage difference, according to a data level, is greater than 1.5V, data identification between levels may be possible. Therefore, the memory device 200 according to example embodiments may read and/or write two-bit data.

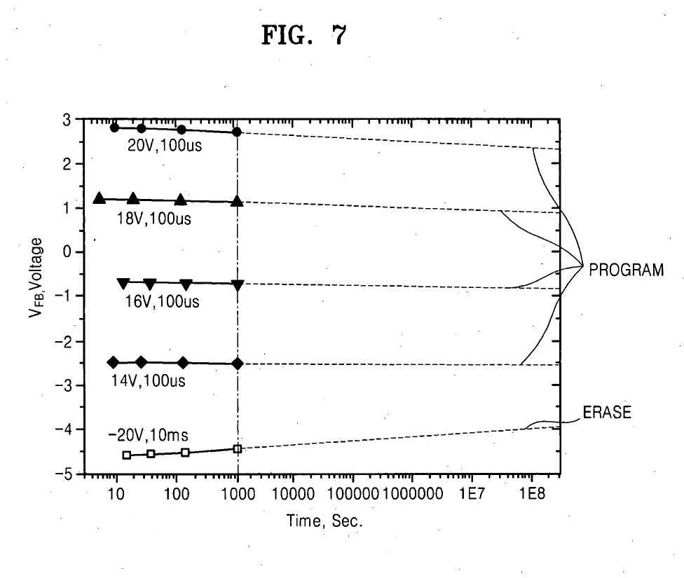

FIG. 7 is a graph showing the flat band voltage of the memory device 200 as a function of time, according to an example embodiment. That is, FIG. 7 is a graph showing measurement results of the variation of flat band voltages according to time, at room temperature, after writing data on the memory device 200 by applying a corresponding bias voltage for 100 μs, and after erasing data by applying a voltage of 20V for 10 milliseconds. The measurement was continued for 1000 seconds, and there was almost no flat band voltage variation in this time period. It is assumed that if this flat band voltage trend was maintained, the flat band voltage would not significantly vary even after 10⁸ seconds, i.e., 3 years. Accordingly, a memory device having a stable multilevel cell may be realized.

As described above, the non-volatile memory device having double traps according to example embodiments may generate a relatively large flat band voltage gap according to applied bias voltage. This may be because the flat band voltage range is more uniformly distributed over positive and negative voltages by a charge trap layer. The charge trap layer may include a hole trap and an electron trap. Accordingly, a stable multilevel cell may be realized.

While example embodiments have been particularly shown and described, it will be understood by those of ordinary skill in the art that various changes in form and details may be made therein without departing from the spirit and scope of the example embodiments as defined by the following claims.

What is claimed is:

1. A memory device, comprising:
a tunnel insulating formed on a substrate;
a charge trap layer on the insulating film, including a hole trap and an electron trap;
a blocking insulating film on the charge trap layer; and
a gate electrode formed on the blocking insulating film.

2. The memory device of claim 1, wherein the hole trap is a first trap layer.

3. The memory device of claim 2, wherein the electron trap is a second trap layer.

4. The memory device of claim 3, wherein the second trap layer is formed on the first trap layer.

5. The memory device of claim 3, wherein the second trap layer is formed of silicon nitride.

6. The memory device of claim 2, wherein the first trap layer is formed of one of a silicon rich oxide and a silicon nano-crystal.

7. The memory device of claim 1, wherein the blocking insulating film is an insulating film having a higher dielectric constant than silicon oxide.

8. The memory device of claim 7, wherein the electron trap is an interface between the blocking insulating film and the first trap layer.

9. The memory device of claim 7, wherein the insulating film is formed of a high k dielectric material.

10. The memory device of claim 9, wherein the high k dielectric material is selected from the group consisting of HfO₂, SiNₓ, Ta₂O₅, Al₂O₃, TiO₂, and PZT.

11. The memory device of claim 1, further comprising a source region and a drain region in the substrate.

12. The memory device of claim 1, wherein the charge trap layer is a storage node that stores multi-bit data.

13. A method of manufacturing a memory device comprising:
forming a tunnel insulating film on a substrate;
forming a charge trap layer formed on the insulating film, including a hole trap and an electron trap;
forming a blocking insulating film on the charge trap layer; and
forming a gate electrode on the blocking insulating film.

14. The method of claim 13, wherein the charge trap layer is a storage node that stores multi-bit data.

15. The method of claim 13, further comprising:
forming a source region and a drain region in the substrate.

16. The method of claim 13, wherein the blocking insulating film is an insulating film having a higher dielectric constant than silicon oxide.

17. The method of claim 16, wherein the electron trap is an interface between the blocking insulating film and the first trap layer.

18. The method of claim 16, wherein the insulating film is formed of a high k dielectric material.

19. The method of claim 18, wherein the high k dielectric material is selected from the group consisting of HfO₂, SiNₓ, Ta₂O₅, Al₂O₃, TiO₂, and PZT.

20. The method of claim 13, wherein,
the hole trap is a first trap layer, and
the electron trap is a second trap layer.

21. The method of claim 20, wherein,
the first trap layer is formed of one of a silicon rich oxide and a silicon nano-crystal, and the second trap layer is formed of silicon nitride.
